(19) United States
(12) Patent Application Publication
(10) Pub. No.: US 2025/0079799 A1
(43) Pub. Date: Mar. 6, 2025

(54) VCSEL WITH INTEGRATED GRATING COUPLER

(71) Applicant: SHENZHEN RAYSEES AI TECHNOLOGY CO., LTD., Shenzhen (CN)

(72) Inventors: Jianyang Zhao; Siva Kumar Lanka, Reno, NV (US); Yongxiang He, Sunnyvale, CA (US); Yang Wang, Hefei (CN)

(73) Assignee: SHENZHEN RAYSEES AI TECHNOLOGY CO., LTD., Shenzhen (CN)

(21) Appl. No.: 18/037,260

(22) PCT Filed: Mar. 16, 2023
(86) PCT No.: PCT/CN2023/081909

§ 371 Date: May 16, 2023

(51) Int. Cl. H01S 5/183

(52) U.S. Cl. CPC H01S 5/18369

(57) ABSTRACT

A system includes a VCSEL element, a dielectric waveguide, and a dielectric grating coupler. The VCSEL element includes a first reflector region, a second reflector region opposite to the first reflector region, and an active region between the first reflector region and second reflector region. The dielectric waveguide is integrated with the VCSEL element. The grating coupler is formed on the dielectric waveguide for coupling an electromagnetic wave of the VCSEL element into the dielectric waveguide.

### FIELD OF INVENTION

This invention generally relates to Vertical Cavity Surface Emitting Lasers (VCSELs) and grating couplers, and specifically to VCSELs with an integrated grating coupler.

### BACKGROUND OF THE INVENTION

Photonic integrated circuits (PICs) provide a powerful platform that enables various applications such as data communications, telecommunications, biochemical sensing, metrology, and light detection and ranging (LiDAR). However, coupling a light source to a PIC component is still a challenge. VCSELs have a vertical cavity and epitaxially grown layers that form distributed Bragg reflectors (DBRs) as mirrors. The advantages of VCSELs include compact size, spectral width, wavelength stability, fast rise time, manufacturability, etc. Coupling a VCSEL with a PIC, especially, coupling a VCSEL with a PIC in an integrated manner is highly desirable.

### SUMMARY OF THE INVENTION

In one aspect, a system includes a Vertical Cavity Surface Emitting Laser (VCSEL) element, a dielectric waveguide, and a dielectric grating coupler. The VCSEL element includes a first reflector region, a second reflector region opposite to the first reflector region, and an active region between the first reflector region and second reflector region. The dielectric waveguide is integrated with the first reflector region. The grating coupler is formed on the dielectric waveguide for coupling an electromagnetic wave of the VCSEL element into the dielectric waveguide.

In another aspect, a system includes a first reflector region, a second reflector region opposite to the first reflector region, an active region between the first reflector region and second reflector region, a dielectric waveguide, and a dielectric grating coupler formed on the dielectric waveguide. The active region and first and second reflector regions are formed for generating an electromagnetic wave traveling along a first direction. The dielectric waveguide is integrated with the first reflector region and extends along a second direction perpendicular to the first direction. The dielectric grating coupler couples a portion of the electromagnetic wave into the dielectric waveguide.

In another aspect, a method for fabricating a system includes forming a first reflector region over a first surface of a substrate, forming an active region over the first reflector region, forming a second reflector region over the active region, forming a dielectric cladding layer over a second surface of the substrate, forming a dielectric core layer over the dielectric cladding layer, forming a waveguide structure based on the dielectric cladding layer and dielectric core layer, and forming a grating coupler on the waveguide structure. The active region and first and second reflector regions are formed for generating an electromagnetic wave traveling along a first direction. The first and second surfaces of the substrate face opposite directions. The waveguide structure is integrated with the substrate and extends along a second direction perpendicular to the first direction. The grating couple is arranged for coupling the electromagnetic wave into the waveguide structure.

### BRIEF DESCRIPTION OF THE DRAWINGS

The subject matter, which is regarded as the invention, is particularly pointed out and distinctly claimed in the claims at the conclusion of the specification. The foregoing and other features and also the advantages of the invention will be apparent from the following detailed description taken in conjunction with the accompanying drawings.

FIG. 1 schematically illustrates a cross-sectional view of a VCSEL structure at a certain stage during a fabrication process, according to embodiments of the present invention.

FIGS. 2 and 3 schematically illustrate cross-sectional views of the VCSEL structure shown in FIG. 1 at certain stages during the fabrication process, according to embodiments of the present invention.

FIG. 4 schematically illustrates a cross-sectional view of a base plate structure, according to embodiments of the present invention.

FIG. 5 schematically illustrates a cross-sectional view after the VCSEL structure shown in FIG. 3 is mounted on the base plate structure, according to embodiments of the present invention.

FIG. 6 schematically illustrates a cross-sectional view after a waveguide structure is formed based on the VCSEL structure, according to embodiments of the present invention.

FIGS. 7 and 8 schematically illustrate cross-sectional views after grating couplers are formed on the waveguide structure, according to embodiments of the present invention.

FIG. 9 schematically illustrates a cross-sectional view of the structure shown in FIG. 8 at a certain stage during the fabrication process, according to embodiments of the present invention.

FIG. 10 schematically illustrates a cross-sectional view of the structure shown in FIG. 9 after a reflector is formed, according to embodiments of the present invention.

FIG. 11 schematically illustrates a cross-sectional view of the structure shown in FIG. 10 at a certain stage during the fabrication process, according to embodiments of the present invention.

FIG. 12 is a flow chart illustrating a schematic fabrication process, according to embodiments of the present invention.

### DETAILED DESCRIPTION

Detailed description of the present invention is provided below along with figures and embodiments, which further clarifies the objectives, technical solutions, and advantages of the present invention. Wherever possible, the same reference numbers are used throughout the drawings to refer to the same or like parts. It is noted that schematic embodiments discussed herein are merely for illustrating the invention. The present invention is not limited to the embodiments disclosed.

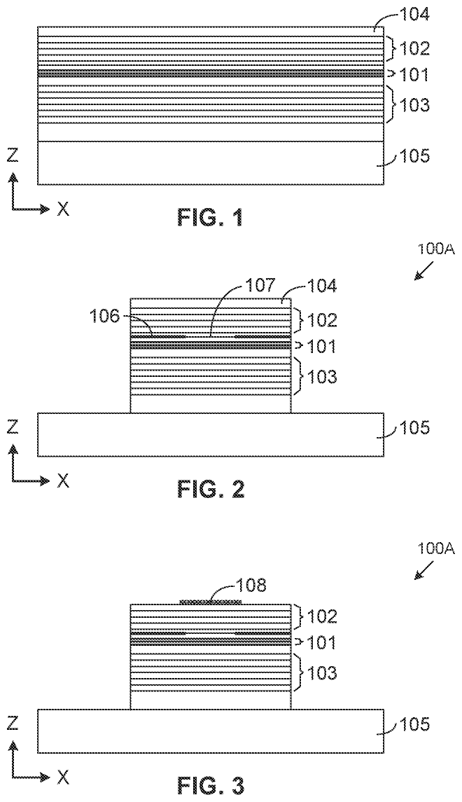

FIG. 1 schematically shows a VCSEL structure in a cross-sectional view at a certain stage of a fabrication process according to embodiments of the present invention. The cross-sectional view is in an X-Z plane. As shown in FIG. 1, the VCSEL structure includes an active region 101, a top reflector region 102, a bottom reflector region 103, a dielectric layer 104, and a substrate 105. Active region 101 may contain a quantum-well configuration such as a multiple-quantum-well (MQW) configuration in some cases. Top and bottom reflector regions 102 and 103 are opposite to each other, and may include a conductive p-type DBR structure and a conductive n-type DBR structure, respectively. In descriptions below, the VCSEL structure is configured as a bottom-emitting VCSEL device. Dielectric layer 104 is deposited over top reflector region 102 and contains a dielectric material such as silicon oxide or silicon nitride. Substrate 105 may be a conductive n-type semiconductor substrate and include, for example, a Group III-V compound such as gallium arsenide (GaAs), indium phosphide (InP), or III-nitride. Bottom reflector region 103, active region 101, and top reflector region 102 may be grown epitaxially and consecutively over a top surface of substrate 105. The top and bottom surfaces of substrate 105 face opposite directions. The epitaxial growth may be performed by molecular beam epitaxy (MBE) or metal organic chemical vapor deposition (MOCVD).

FIGS. 2 and 3 schematically show cross-sectional views of the VCSEL structure shown in FIG. 1 at certain stages during the fabrication process according to embodiments of the present invention. After the epitaxial growth and deposition of layer 104, in certain aspects, dry etch or a combination of dry etch and wet etch is performed to remove certain portions of the epitaxial structure over substrate 105, creating a mesa configuration. The etch process exposes sides of the epitaxial layers in active region 101 and top and bottom reflector regions 102 and 103. Optionally, a high aluminum (Al)-content layer (not shown) may be arranged between top reflector region 102 and active region 101. The high Al-content layer has relatively high Al content compared to other layers. The sides of the high Al-content layer are also exposed in the mesa configuration.

Thereafter, a timed oxidation process is performed using hot water vapor or in a dry oxygen environment. As the oxidation rate is strongly dependent on the Al-content, the high rate of oxidation of the high Al-content layer creates an oxide layer 106 that forms an oxide aperture 107, as shown in FIG. 2. Oxide aperture 107 is configured between top reflector region 102 and active region 101 and arranged for concentrating the electrical current within a central axial portion of the VCSEL structure. The VCSEL structure as shown in FIG. 2 may be referred to as a VCSEL device 100A. As aforementioned, VCSEL 100A is a bottom-emitting VCSEL device, i.e., an output beams is emitted through bottom reflector region 103 and substrate 105. Thereafter, dielectric layer 104 is removed in a selective etch process such as a selective wet etch process to expose a surface of top reflector region 102.

Further, a metal deposition process is performed to form a metal layer 108 over the surface of top reflector region 102. For example, a photoresist layer (not shown) may be deposited. A part of the photoresist layer may be exposed and developed. Another part of the photoresist layer that is not exposed and developed may be removed. Then, metal layer 108 may be deposited in the area where the photoresist layer is removed in a lift-off process, as shown in FIG. 3. Metal layer 108 is the p-metal contact that is electrically connected to top reflector region 102.

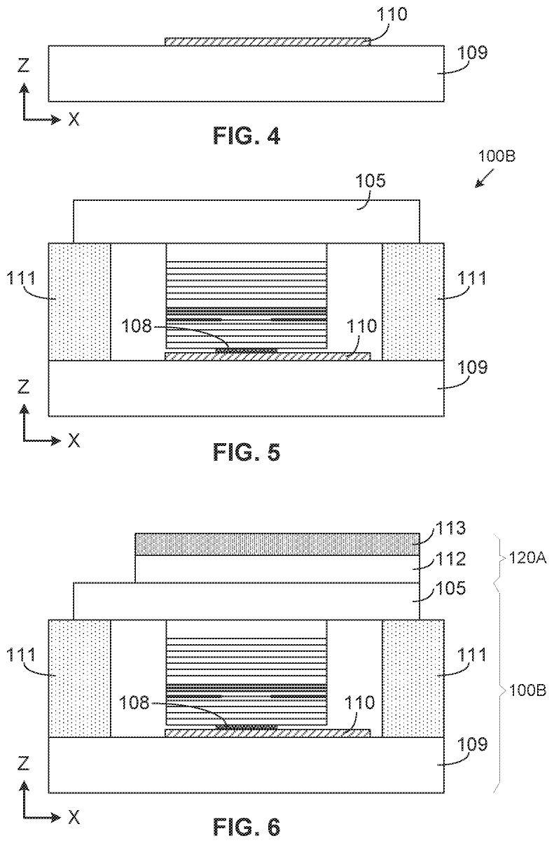

FIG. 4 schematically shows a cross-sectional view of a base plate structure according to embodiments of the present invention. The base plate structure works as a mount and heat sink for the VCSEL structure. The base plate structure includes a base plate 109 made from a material of high thermal conductivity. In some cases, an electrically conductive layer 110 is deposited on base plate 109. Material options for base plate 109 may include sapphire, SiC, diamond, AlN, or other materials with high thermal conductivity. Options for conductive layer 110 may include one or more metallic materials, for example, copper or gold.

FIG. 5 schematically shows a cross-sectional view after VCSEL device 100A shown in FIG. 3 is bonded with the base plate structure according to embodiments of the present invention. The combination of device 100A and the base plate structure creates a mounted bottom-emitting VCSEL structure, which may be referred to as VCSEL device 100B. In certain embodiments, a flip-chip bonding process is implemented. For example, VCSEL device 100A may be flipped over vertically and become upside down with the top surface of metal layer 108 facing downward. Then, VCSEL device 100A and the base plate structure are placed together such that metal layer 108 is above and aligned with conductive layer 110. After the alignment is made, a bonding process is performed to bond metal layer 108 with conductive layer 110, which forms VCSEL device 100B. Optionally, a portion of conductive layer 110 may be arranged away from the flip-chip bonding area or VCSEL device 100A. This portion of conductive layer 110 may be used as a contact pad for VCSEL device 100B, where bond wires may be bonded.

Further, support components 111 may be disposed between substrate 105 and base plate 109 to construct a support structure. Support components 111 may be made from electrically insulating materials, and attached to substrate 105 and base plate 109 by an adhesive epoxy compound.

FIGS. 6 and 7 schematically show cross-sectional views of a system 130A at certain fabrication stages according to embodiments of the present invention. After the flip-chip bonding process, the bottom surface of substrate 105 faces upward. In some aspects, substrate 105 may be thinned by a thinning process, such as wafer grinding, dry etch, wet etch, chemical mechanical polishing (CMP), or a combination thereof. The thinning process may be arranged to control the thickness of substrate 105 and adjust the optical path length of the output beam.

Further, a waveguide cladding layer 112 is deposited over the bottom surface of substrate 105 by chemical vapor deposition (CVD), physical vapor deposition (PVD), atomic layer deposition (ALD), or a combination thereof. The CVD process, as used herein, may include low pressure chemical vapor deposition (LPCVD) and/or plasma-enhanced chemical vapor deposition (PECVD). Layer 112 is grown for building a dielectric planar waveguide system 120A. In some aspects, waveguide cladding layer 112 may be formed by depositing a dielectric material such as silicon dioxide (SiO₂). Optionally, one or more additional layers may be deposited over substrate 105 before depositing layer 112. The one or more additional layers may be arranged to reduce reflection by waveguide cladding layer 112 when an output beam is emitted from VCSEL 100B.

Thereafter, a waveguide core layer 113 is deposited over cladding layer 112 by CVD, PVD, ALD, or a combination thereof, as shown in FIG. 6. Waveguide core layer 113 is fabricated as the waveguide core for waveguide system 120A. In some aspects, waveguide core layer 113 may be formed by depositing a dielectric material that has a refractive index larger than that of the waveguide cladding layer 112, such as silicon nitride (Si₃N₄).

Further, patterning and etch processes are performed to etch waveguide core layer 113, creating channel waveguides, and forming waveguide system 120A. Exemplarily, waveguide system 120A contains a Si₃N₄ core with an upper air cladding and lower SiO₂ cladding design. The thickness of waveguide core layer 113 may be determined according to the wavelength of the output beam of VCSEL device 100B.

As shown in FIG. 7, system 130A contains waveguide system 120A and VCSEL device 100B as two elements. VCSEL device 100B has a bottom-emitting mechanism and emits an output beam 114 through substrate 105 along the Z direction or the vertical direction. The term “beam” as used herein indicates an electromagnetic wave traveling in free space, a matter, or a waveguide. As waveguide system 120A supports beams propagating in an X-Y plane, i.e., along an in-plane direction, a grating coupler 117 is configured to couple beam 114 into waveguide system 120A. Coupler 117 is a dielectric grating coupler. Grating coupler 117 is adjacent to substrate 105 and bottom reflector region 103 and integrated with VCSEL device 100B. Grating coupler 117 changes the direction of light from a vertical direction to an in-plane direction. For example, grating coupler 117 splits beam 114 into beams 115A and 116A, which propagate against and along the X direction, respectively. Besides beams 115A and 116A, a part (not shown) of beam 114 is not redirected, remains a vertical beam, and exits the waveguide.

Grating coupler 117 includes a periodic structure configured along the X direction. The periodic structure has a period larger than the wavelength of the light (e.g., beam 114). The periodic structure may be made by depositing certain materials on the top surface of the waveguide core, or etching openings on the top surface of the waveguide core. As exemplarily shown in FIG. 7, grating coupler 117 is formed by etching periodic openings on the waveguide core. Coupler 117 is a one-dimensional (ID) grating coupler. To make the periodic structures, high-resolution pattering may be performed by electron beam lithography (EBL) or deep UV (DUV) lithography. The periodic structure causes a periodic change of the refractive index (e.g., in the X direction as shown in FIG. 7). When a vertical beam (e.g., beam 114) impinges on the periodic structure, the beam is diffracted and part of the diffracted beam is coupled in the direction of index variation. As an example, grating coupler 117 is arranged to direct a vertical beam to travel in a horizontal direction or in-plane direction. When beam 114 is diffracted by grating coupler 117, the diffracted light interferes constructively in the direction against or along the X axis, forming beams 115A and 116A, respectively.

When a grating coupler is made by etching a waveguide core, the etch depth may be smaller than the thickness of the waveguide core in some embodiments. Alternatively, the etch depth may equal the thickness of the waveguide core in some other embodiments. In these cases, the opening in the periodic structure exposes a part of the lower cladding layer.

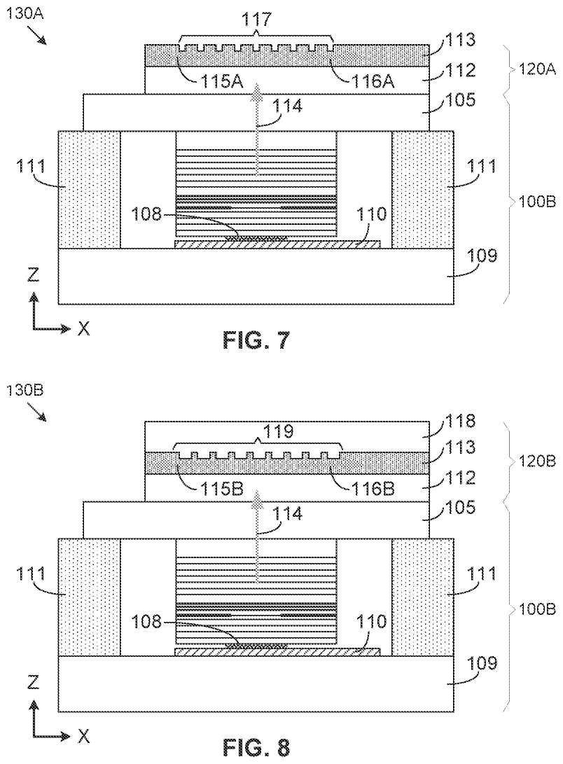

FIG. 8 schematically shows a cross-sectional view of a system 130B according to embodiments of the present invention. System 130B contains a dielectric planar waveguide system 120B and VCSEL device 100B. As shown in FIG. 8, waveguide system 120B has SiO₂ waveguide cladding layer 112, Si₃N₄ waveguide core layer 113, and another SiO₂ waveguide cladding layer 118. Optionally, Si₃N₄ waveguide core layer 113 may be embedded in a surrounding SiO₂ cladding material. In order to couple beam 114 into waveguide system 120B, a ID dielectric grating coupler 119 is formed. Grating coupler 119 splits beam 114 into beams 115B and 116B, which propagate in the waveguide against and along the X direction, respectively. Besides beams 115B and 116B, a portion (not shown) of beam 114 is not redirected, remains a vertical beam, and exits the waveguide.

Grating coupler 119 is adjacent to substrate 105 and bottom reflector region 103 and integrated with VCSEL device 100B. Grating coupler 119 includes a periodic structure configured in the X direction exemplarily. The periodic structure has a period larger than the wavelength of the light (e.g., beam 114). The periodic structure may be made by depositing certain materials on the top surface of the waveguide core or creating openings on the top surface of the waveguide core. As an example, grating coupler 119 is formed by etching openings on the waveguide core and then depositing SiO₂ materials to grow layer 118 by CVD, PVD, ALD, or a combination thereof. The SiO₂ materials cover or bury the openings and waveguide core. In some cases, high-resolution patterning may be performed by EBL or DUV lithography before the openings are etched on the waveguide core. Grating coupler 119 is arranged to split an incoming beam (e.g., beam 114) traveling in a vertical direction into beams (e.g., beams 115B and 116B) traveling along in-plane directions, and couple the beams into waveguide system 120B. When grating coupler 119 is made by etching waveguide core layer 113, the etch depth may be smaller than the thickness of layer 113 in some embodiments. Optionally, the etch depth may equal the thickness of layer 113 in some other cases.

As illustrated above, waveguide cladding layer 112 and waveguide core layer 113 may be deposited by CVD and/or ALD. In some cases, the waveguide cladding layer is SiO₂ and the waveguide core is Si₃N₄. In some other cases, MBE or MOCVD may be used and waveguide cladding layer 112 and waveguide core layer 113 may be made by epitaxial growth. However, the epitaxial growth limits materials for the waveguide core and cladding layers. For example, an epitaxially grown waveguide based on a GaAs substrate may have a GaAs core and Al_{0.3}Ga_{0.7}As cladding layer. Compared to Si₃N₄, which benefits from transparency over the visible and infrared wavelength range (e.g., 400-2350 nm), GaAs is only transmissive in the infrared wavelength range. As such, applications of the epitaxially grown waveguides are restricted. With the non-epitaxial deposition method, waveguide systems 120A and 120B may be made for the visible and infrared light range. With the epitaxial growth method, however, waveguide systems 120A and 120B can only be made for the infrared light range.

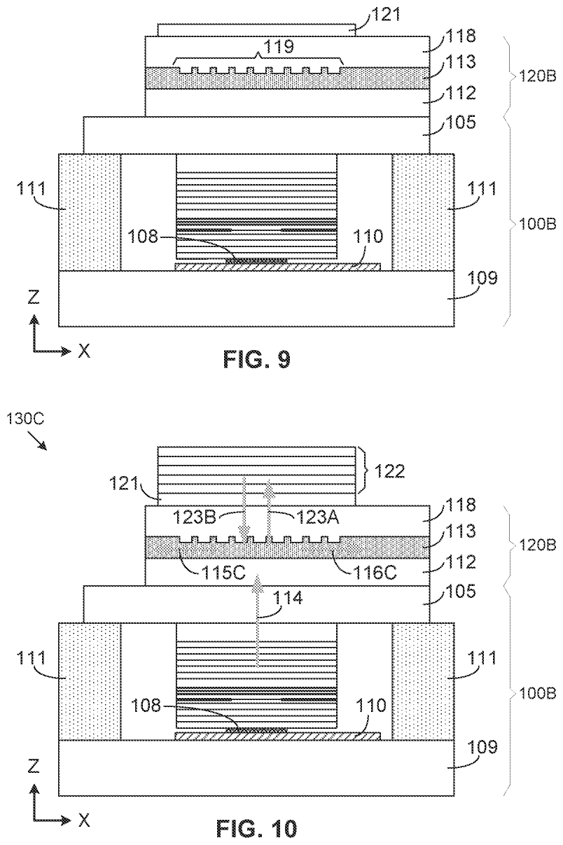

FIGS. 9-11 schematically show a system 130C at certain fabrication stages according to embodiments of the present invention. Similar to system 130B, system 130C contains waveguide system 120B and VCSEL device 100B. As mentioned above, a portion of beam 114 is not coupled into the waveguide system and instead, it radiates outside the waveguide. This portion of beam 114 represents a coupling loss. In order to increase the coupling efficiency of grating coupler 119, a reflector 122 is configured. Before making reflector 122, the top surface of layer 118 may be planarized using, e.g., CMP. Further, a material (e.g., SiO₂) is deposited to grow a spacer layer 121 over layer 118 and grating coupler 119, as shown in FIG. 9. Thereafter, reflector 122 is formed over layer 121. In some embodiments, reflector 122 may include alternating dielectric layers that form a dielectric DBR mirror structure. Spacer layer 121 and the dielectric DBR mirror structure may be deposited by CVD. PVD, ALD, or a combination thereof.

As shown in FIG. 10, when beam 114 impinges on grating coupler 119, beam 114 is split into three portions, corresponding to beams 115C, 116C, and 123A. Beam 115C and 116C are coupled into the waveguide, while beam 123A propagates towards reflector 122 and reflected by the reflector. A beam 123B, representing the reflected beam, impinges on grating coupler 119 and parts of beam 123B are coupled into the waveguide. The thickness of spacer layer 121 is arranged such that when portions of beams 114 and 123B are coupled into the waveguide and mixed together, these portions are in phase. As such, more light is coupled into waveguide system 120B. Similarly, the thickness of substrate 105 may also be adjusted for the in-phase condition. Hence, the coupling efficiency of grating coupler 119 may be increased by reflector 122.

Reflector 122 may have various types. For example, a metallic material (e.g., gold) may be deposited on spacer layer 121 to form a metal layer by CVD or PVD. The metal layer may function as a reflector. In some other cases, a reflector may also be premade and then bonded on spacer layer 121 to create a reflected beam (e.g., beam 123B).

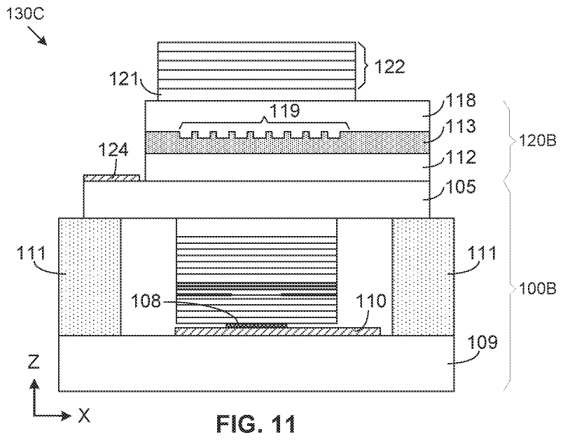

Further, a metal layer 124 is deposited on substrate 105 to form the n-metal contact by CVD or PVD, as shown in FIG. 11. The n-metal contact may be connected to a contact pad of system 130C. Thereafter, other fabrication processes and certain packaging processes may be implemented to make system 130C. These processes are omitted.

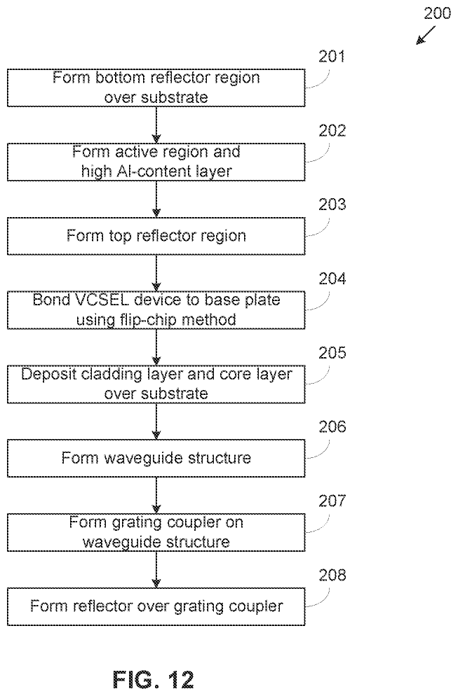

FIG. 12 is a flow chart illustrating a schematic fabrication process 200 for a system containing a bottom-emitting VCSEL device and a dielectric planar grating coupler, according to embodiments of the present invention. Process 200 starts from proving a substrate such as an n-type III-V semiconductor wafer. At step 201, multiple layers as a bottom reflector region are grown epitaxially over the top surface of the substrate. The bottom reflector region includes a DBR structure. At step 202, an active region is grown epitaxially. The active region may include a MQW configuration. Further, a high Al-content layer is deposited epitaxially. Alternatively, the high Al-content layer may also be deposited between step 201 and step 202. At step 203, multiple layers as a top reflector region are grown epitaxially. The top reflector region includes another DBR structure. Further, a dry etch process or dry etch and wet etch processes are performed. The etch process removes certain parts of the active region and the top and bottom reflector regions to form a mesa structure. Sides of the high Al-content layer are exposed. An oxidizing process is implemented to oxidize the high Al-content layer to form an oxide layer and an oxide aperture. A bottom-emitting VCSEL structure is made.

At step 204, the VCSEL structure is turned over and bonded with a base plate or a mount by a flip-chip method. The bottom surface of the substrate of the VCSEL structure becomes facing upward. At step 205, dielectric materials are deposited over the bottom surface of the substrate to form a waveguide cladding layer and a waveguide core layer consecutively. In some cases, the waveguide cladding layer and core layer may be formed by depositing SiO₂ and Si₃N₄, respectively. Before depositing cladding materials to form the waveguide cladding layer, a CMP process may be performed to make the substrate thinner and planarized.

At step 206, patterning and etch processes are performed to etch the waveguide core layer to create a dielectric planar waveguide structure. The waveguide structure is integrated with the VCSEL structure. The waveguide structure extends in a plane perpendicular to the propagation direction of the output beam of the VCSEL. In some cases, the waveguide core is surrounded by the dielectric cladding material. Optionally, the waveguide may have upper air cladding and lower dielectric material cladding.

At step 207, a grating coupler is fabricated on the waveguide core. In some embodiments, an etch process is conducted to etch periodic structures on the waveguide core. In some other embodiments, a deposition is conducted to deposit periodic structures on the waveguide core. In some cases, cladding materials are deposited to cover the grating coupler and surround the waveguide core. The grating coupler changes the direction of the light emitted from the VCSEL and couples it into the waveguide.

At step 208, a planarization process is performed after the grating coupler is buried by the cladding material. A spacer layer is deposited over the grating coupler. Further, a reflector is formed over the spacer layer. In some embodiments, the reflector is made by depositing alternating dielectric layers that form a DBR structure. Optionally, a metal layer may be deposited on the spacer layer to form a reflector. The reflector reflects the light that is not coupled into the waveguide. The reflected light impinges on the grating coupler and part of the reflected light is coupled into the waveguide. The coupling efficiency of the grating coupler may be increased by the reflector.

As illustrated above, a system may include three elements: a VCSEL, a waveguide, and a grating coupler. Optionally, a system may also include four elements: a VCSEL, a waveguide, a grating coupler, and a reflector. In these cases, the three or four elements are integrated together. The waveguide and grating coupler are formed over the substrate of the VCSEL. The grating coupler couples the VCSEL with the waveguide. The reflector is formed over the grating coupler to increase the coupling efficiency of the grating coupler. The method of fabricating the waveguide and grating coupler is compatible with production processes of VCSELs.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments. Furthermore, it is intended that the appended claims cover any and all such applications, modifications, and embodiments within the scope of the present invention.

We claim:

1. A system, comprising:
a Vertical Cavity Surface Emitting Laser (VCSEL) element, the VCSEL element including:
a first reflector region;
a second reflector region opposite to the first reflector region; and
an active region between the first reflector region and second reflector region;
a dielectric waveguide integrated with the first reflector region; and
a dielectric grating coupler formed on the dielectric waveguide for coupling an electromagnetic wave of the VCSEL element into the dielectric waveguide.

2. The system of claim 1, wherein the first reflector region and the second reflector region each comprise a distributed Bragg reflector (DBR) structure.

3. The system of claim 1, wherein the active region includes a quantum-well configuration.

4. The system of claim 1 further comprising a reflector, the dielectric grating coupler disposed between the reflector and the first reflector region.

5. The system of claim 4, wherein the reflector includes a dielectric distributed Bragg reflector (DBR) structure.

6. The system of claim 1, wherein the waveguide includes a dielectric core material and a dielectric cladding material.

7. The system of claim 1, wherein the VCSEL element further includes a substrate, the dielectric waveguide formed over a surface of the substrate.

8. A system, comprising:
a first reflector region;
a second reflector region opposite to the first reflector region;
an active region between the first reflector region and second reflector region, the active region and first and second reflector regions formed for generating an electromagnetic wave traveling along a first direction;
a dielectric waveguide integrated with the first reflector region and extending along a second direction perpendicular to the first direction; and
a dielectric grating coupler formed on the dielectric waveguide to couple a portion of the electromagnetic wave into the dielectric waveguide.

9. The system of claim 8, wherein the first reflector region and the second reflector region each comprise a distributed Bragg reflector (DBR) structure.

10. The system of claim 8, wherein the active region includes a quantum-well configuration.

11. The system of claim 8 further comprising a reflector, the dielectric grating coupler disposed between the reflector and the first reflector region.

12. The system of claim 11, wherein the reflector includes a dielectric distributed Bragg reflector (DBR) structure.

13. The system of claim 8, wherein the waveguide includes a dielectric core material and a dielectric cladding material.

14. The system of claim 8, wherein the first reflector region is formed over a first surface of a substrate, the dielectric waveguide is formed over a second surface of the substrate, and the first and second surfaces face opposite directions.

15. A method for fabricating a system, comprising:
forming a first reflector region over a first surface of a substrate;
forming an active region over the first reflector region;
forming a second reflector region over the active region, the active region and first and second reflector regions formed for generating an electromagnetic wave traveling along a first direction;
forming a dielectric cladding layer over a second surface of the substrate, the first and second surfaces of the substrate facing opposite directions;
forming a dielectric core layer over the dielectric cladding layer;
forming a waveguide structure based on the dielectric cladding layer and dielectric core layer, the waveguide structure integrated with the substrate and extending along a second direction perpendicular to the first direction; and
forming a grating coupler on the waveguide structure for coupling the electromagnetic wave into the waveguide structure.

16. The method of claim 15, wherein the first reflector region and the second reflector region each comprise a distributed Bragg reflector (DBR) structure.

17. The method of claim 15, wherein the active region includes a quantum-well configuration.

18. The method of claim 15 further comprising forming a reflector over the grating coupler.

19. The method of claim 18, wherein the reflector includes a dielectric distributed Bragg reflector (DBR) structure.

20. The method of claim 15, wherein forming the grating coupler includes forming a periodic structure along the second direction on the waveguide structure.
